(19) United States
(12) Patent Application Publication
(10) Pub. No.: US 2006/0198100 A1
(43) Pub. Date: Sep. 7, 2006

(54) Electric power generating device

(76) Inventor: Chen-Hui Hsien, Jhongli City (TW)

Correspondence Address: CHARLES E. BAXLEY, ESQ., 90 JOHN STREET, THIRD FLOOR, NEW YORK, NY, 10038, US

(21) Appl. No.: 11/069,677

(22) Filed: Mar. 1, 2005

(51) Int. Cl. H05K 5/00

(52) U.S. Cl. 361/687

(57) ABSTRACT

An electric power generating device includes an air ventilation device which rotates due to air flow and an electric power generating module is connected to the air ventilation device and co-rotated with the air ventilation device. A control module is connected to the electric power generating and an auxiliary power supply. An output module is connected to the control module and an electric appliance. The rotation of the power generating module generates electric power by the air ventilation device to power the appliance. When the air flow is not less than expected, the auxiliary power supply takes over to power the appliance.

### FIELD OF THE INVENTION

The present invention relates to an electric power generating device by using a rotatable air ventilation device.

### BACKGROUND OF THE INVENTION

The weather of the earth changes dramatically and scientists point out that the globe warming is one of the important factors that affect the weather on earth. The globe warming is mainly related to the carbon dioxide which is generated in every types of burning of energy. People are forced to face the serious problem and begin to develop new and cheap energy such as hydraulic power, wind power and solar power. However, all the new sources of power are limited by the geographic conditions. The solar power cannot be collected during nights, and the hydraulic power requires high speed and volume of moving water. The wind generally is not a constant air flow which might not meet requirement for generating power.

The present invention intends to provide a power generating device that is cooperated with an air ventilation device which rotates because of the warm air goes upward and cool air goes down so that, theoretically, the air ventilation device keeps rotating all the time. The ventilation device is connected with a rotatable member which transfers kinetic energy into electric power.

### SUMMARY OF THE INVENTION

The present invention relates to an electric power generating device that comprises an air ventilation device and an electric power generating module co-rotatably connected to the air ventilation device. A control module is connected to the electric power generating module and an output module is connected to the control module. An auxiliary power supply is connected to the control module.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows a block diameter of the electric power generating device of the present invention;

FIG. 2 is an exploded view to show the air ventilation device and the electric power generating module of the present invention;

FIG. 3 is a perspective view to show the combination of the air ventilation device and the electric power generating module of the present invention;

FIG. 4 is an exploded view of another embodiment of the air ventilation device and the electric power generating module of the present invention, and

FIG. 5 is a perspective view to show the combination of the air ventilation device and the electric power generating module of disclosed in FIG. 4.

### DETAILED DESCRIPTION OF THE PREFERRED EMBODIMENT

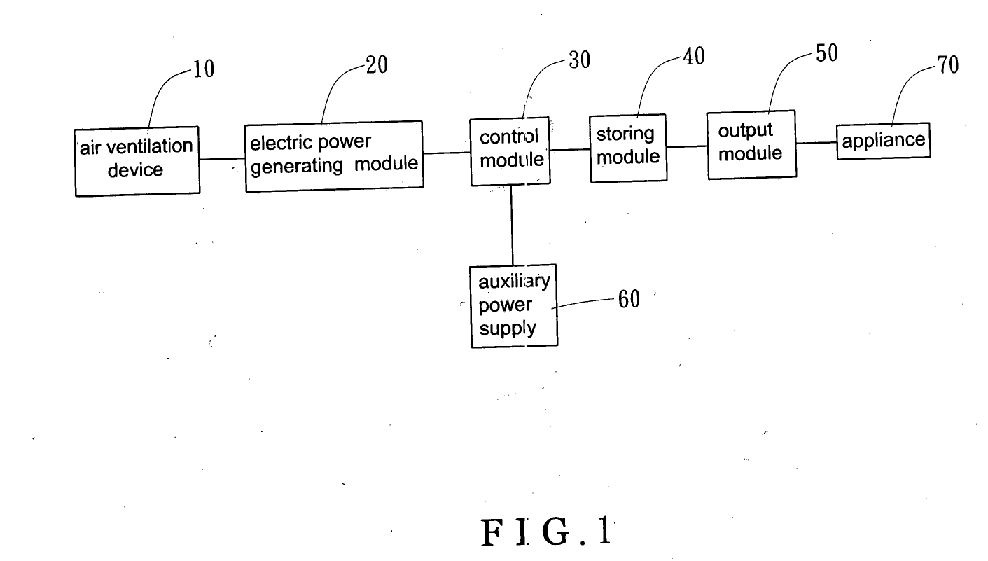

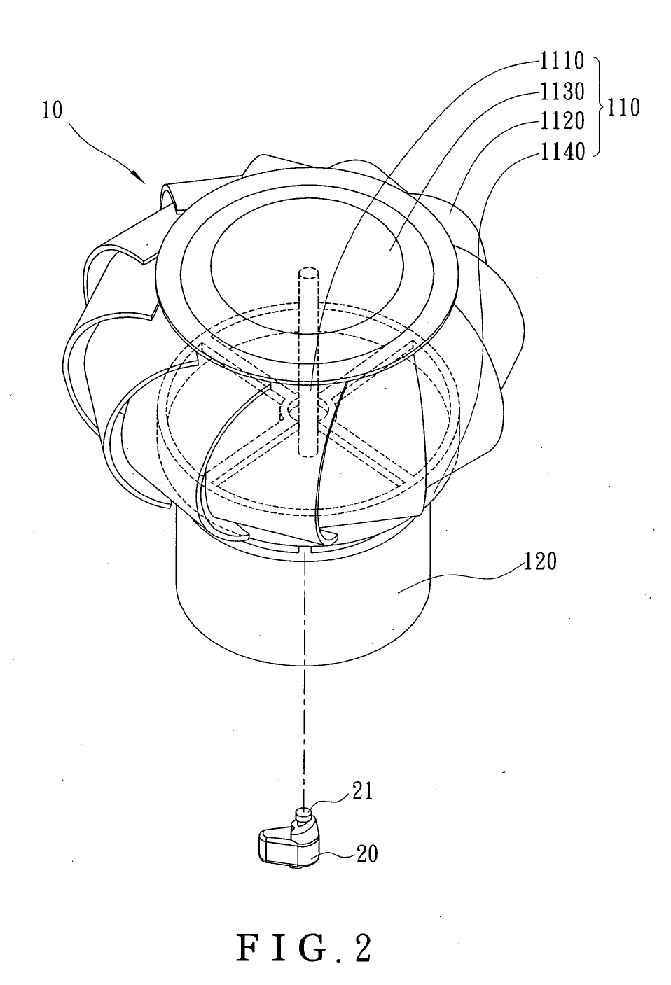

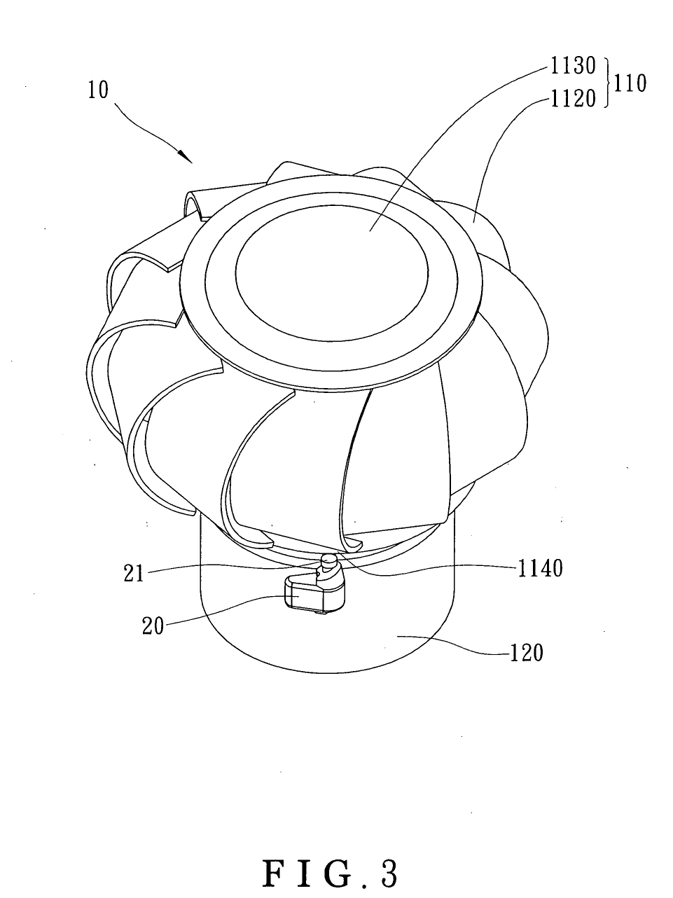

Referring to FIGS. 1 to 3, the electric power generating device of the present invention comprises an air ventilation device 10, an electric power generating module 20 connected to the air ventilation device 10, a control module 30 connected to the electric power generating module 20, an output module 50 connected to the control module 30, and an auxiliary power supply 60 connected to the control module 30.

The electric power generating module 20 transfers kinetic power into electric power and the control module 30 switches the current from DC to AC, or vice versa. The control module 30 also monitors that the electric power that generates from the electric power generating module 20. If the power that the electric power generating module 20 provides is not stable or is less than expected, the control module 30 is switches the circuit to the auxiliary power supply 60 which can be the local power plant so as to ensure the quality of the electric power.

A storing module 40 can be connected between the control module 30 and the output module 50 and the output module 50 is connected to an appliance 70 which is powered by the electric power generated by the electric power generating module 20.

The air ventilation device 10 is a turbine 110 which includes a shaft 1110 with a top cap 1130 and a bottom cap 140 connected to two ends of the shaft 1110. A base 120 is connected to the bottom cap 1130. A plurality of curve blades 1120 are connected between the top cap 1130 and the bottom cap 140. A gap is defined between adjacent blades 1120 so that warm air goes upward and through the gaps between the blades 1120 which are shaped that the warm air flow rotates the blades 120 together with the shaft 1110. The electric power generating module 20 includes a rotor 21 which is connected to the bottom cap 140 so that when the air ventilation device 10 rotates, the rotor 21 rotates and generates electric power.

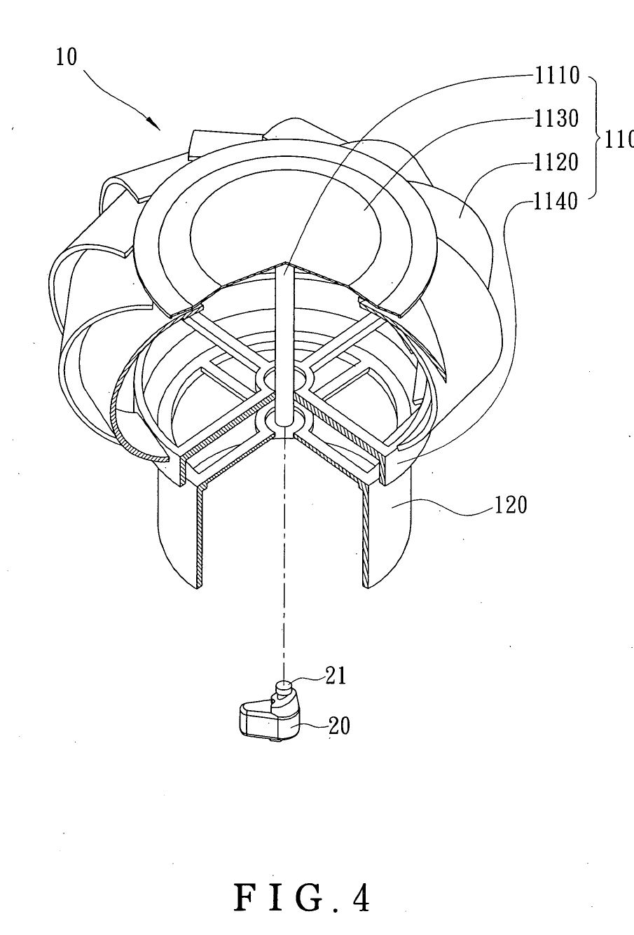

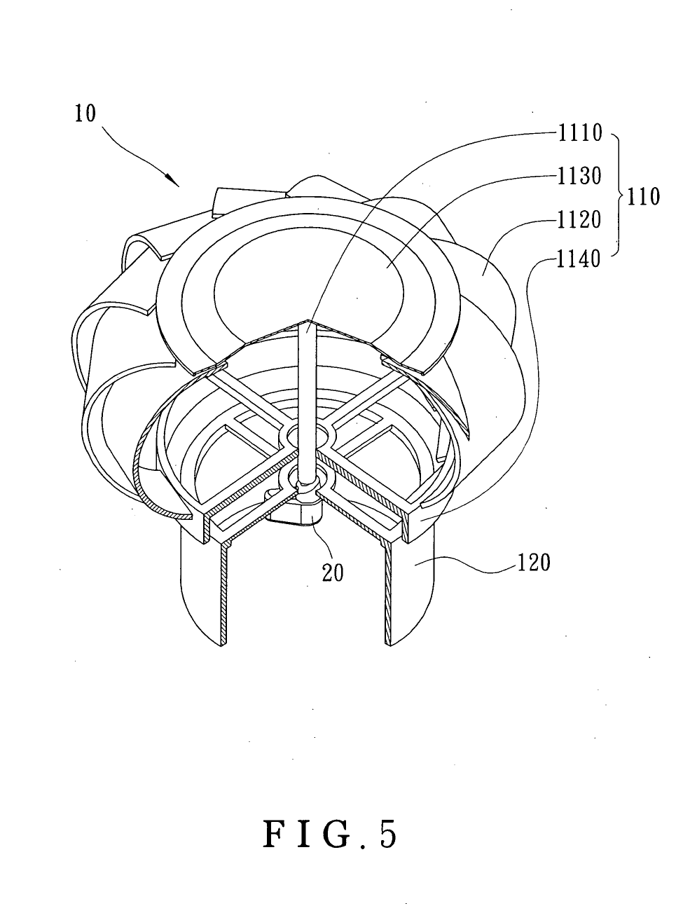

As shown in FIGS. 4 and 5, the rotor 21 can also be directly connected to the shaft 1110 which rotates the rotor 21 to generate electric power.

While we have shown and described the embodiment in accordance with the present invention, it should be clear to those skilled in the art that further embodiments may be made without departing from the scope of the present invention.

What is claimed is:

1. An electric power generating device comprising:
an air ventilation device, an electric power generating module connected to the air ventilation device, a control module connected to the electric power generating module, an output module connected to the control module, an auxiliary power supply connected to the control module.

2. The device as claimed in claim 1, wherein a storing module is connected between the control module and the output module.

3. The device as claimed in claim 1, wherein the output module is connected to an appliance.

4. The device as claimed in claim 2, wherein the output module is connected to an appliance.

5. The device as claimed in claim 1, wherein the air ventilation device includes a shaft with a top cap and a bottom cap connected to two ends of the shaft, a plurality of curve blades are connected between the top cap and the bottom cap, a gap is defined between adjacent blades.
